(19) United States
(12) Patent Application Publication
(10) Pub. No.: US 2016/0126238 A1
(43) Pub. Date: May 5, 2016

(54) POWER SOURCE CIRCUIT, ELECTRONIC CIRCUIT, AND INTEGRATED CIRCUIT

(71) Applicant: SOCIONEXT INC., Yokohama-shi (JP)

(72) Inventors: Akimitsu TAJIMA, Hachioji (JP); Yuji ITO, Hachioji (JP)

(21) Appl. No.: 14/928,828

(22) Filed: Oct. 30, 2015

(30) Foreign Application Priority Data
Nov. 4, 2014 (JP) 2014-224587

(51) Int. Cl. H01L 27/02; G05F 3/16; H01L 27/092

(52) U.S. Cl. CPC H01L 27/0274; H01L 27/0921; G05F 3/16

(57) ABSTRACT

A power source circuit includes: a P-type transistor one of a source and a drain of which is connected to a first power source line and the other of the source and the drain of which is connected to an output node; a resistor connected between a back gate of the P-type transistor and the first power source line; and a capacitance element connected to the back gate of the P-type transistor and to a second power source line having a potential lower than a potential of the first power source line.

### CROSS-REFERENCE TO RELATED APPLICATION

This application is based upon and claims the benefit of priority of the prior Japanese Patent Application No. 2014-224587, filed on Nov. 4, 2014, the entire contents of which are incorporated herein by reference.

### FIELD

The technique disclosed herein relates to a power source circuit, an electronic circuit, and an integrated circuit.

### BACKGROUND

A processing circuit, such as a CPU core logic circuit, an analog circuit, an I/O circuit, and an interface circuit, operates by receiving supply of power source. The supply of power includes the case where a necessary power source is supplied from the outside to a power source terminal provided in an integrated circuit (IC) chip mounting a processing circuit and the case where an external power source is supplied to a power source circuit mounted on an IC chip via a power source terminal and the power source circuit generates a power source for the processing circuit. Such a power source circuit is referred to as a regulator.

For example, implementing a processing system is performed by mounting a plurality of processing circuits, such as a CPU core logic circuit, an analog circuit, an I/O circuit, and an interface circuit, on one board (printed circuit board). In one configuration, a power source circuit that generates various direct-current (DC) power sources required in a plurality of processing circuits from an electric light line (AC power source) is provided outside the board and a plurality of power sources is supplied to a plurality of power source terminals of the board from the power source circuit. In another configuration, the power source circuit is mounted on a board and the AC power source is supplied to the board from the electric light line.

There is a case where the power sources that are supplied to a plurality of processing circuits differ not only in power source voltage but also in power source quality. For example, the power source of the CPU core logic circuit and the analog circuit has a voltage of 1.2 V, the power source of the I/O circuit has a voltage of 3.3 V, and the power source of the high-speed interface circuit has a voltage of 1.8 V. The power source of the CPU core logic circuit and the analog circuit has the same voltage, i.e., 1.2 V, but it is desirable that the power source of the analog circuit be a power source with less ripples and have good voltage stability, while the power source of the CPU core logic circuit accepts comparatively low voltage stability. Consequently, the power source circuit generates a low-voltage DC power source, such as 3.3 V, from the AC power source by using a step-down circuit or a switching power source circuit that utilizes a transformer, and generates a base DC power source with good voltage stability by utilizing a large-capacity capacitance element or the like. The power source that is supplied to the CPU core logic circuit is generated by a switching regulator from the base DC power source and the power sources of the analog circuit and the high-speed interface circuit are generated by a linear regulator, respectively, and the power source of the I/O circuit is supplied as it is.

In recent years, a system on a chip (SoC) is being widely used, in which a processing system is implemented by one IC chip by mounting a plurality of processing circuits, such as a CPU core logic circuit, an analog circuit, an I/O circuit, and an interface circuit, on one IC chip. The case of the SoC also includes the case where each of a plurality of power sources is supplied from the outside to a plurality of processing circuits and the case where the base DC power source is supplied to the SoC and various regulators are provided within the SoC. It is common to connect an inductance element (coil) and a capacitance element (capacitor) that are used in a switching regulator to the IC chip as discrete parts, but there is a case where the inductance element and the capacitance element are mounted on the SoC.

In embodiments explained below, a case is explained as an example where a regulator is mounted on a board or IC chip and a base DC power source is supplied to the regulator of the board or IC chip.

There is a case where a high voltage is applied to the power source line due to static electricity though the application time is short, and if such a high voltage is applied, there is a possibility that a failure will occur in the regulator and in the processing circuit to which the base DC power source is supplied even though the application time is short. Consequently, an electrostatic discharge (ESD) protection circuit is provided in the power source line.

In the case where the regulator is mounted on the board or IC chip and the base DC power source is supplied to the regulator of the board or IC chip, the ESD protection circuit is provided in the vicinity of the terminal of the board or IC chip, to which the base DC power source is supplied.

In a general ESD protection circuit, a transistor is connected between a high potential side power source line and a low potential side power source line of a power source and a control is performed so that the transistor turns off when the power source is turned on and during the normal time and when a surge voltage due to static electricity is applied, the transistor turns on temporarily. Due to this, a high voltage is prevented from being applied to a circuit element connected between the high potential side power source line and the low potential side power source line for a predetermined period of time or longer when a surge voltage is applied. In order to perform such control of the transistor, a time constant circuit that utilizes a resistor and a capacitance element is used and the ESD protection circuit returns to the normal state after discharging the surge voltage.

### RELATED DOCUMENTS

[Patent Document 1] Japanese Laid Open Patent Publication No. 2005-64374

### SUMMARY

According to a first aspect of embodiments, a power source circuit includes: a P-type transistor one of a source and a drain of which is connected to a first power source line and the other of the source and the drain of which is connected to an output node; a resistor connected between a back gate of the P-type transistor and the first power source line; and a capacitance element connected to the back gate of the P-type transistor and to a second power source line having a potential lower than a potential of the first power source line.

According to a second aspect of embodiments, an electronic circuit includes: a processing circuit; and

a power source circuit which supplies a power source voltage to the processing circuit, wherein the power source circuit includes: a P-type transistor one of a source and a drain of which is connected to a first power source line and the other of the source and the drain of which is connected to an output node; a resistor connected between a back gate of the P-type transistor and the first power source line; and a capacitance element connected to the back gate of the P-type transistor and to a second power source line having a potential lower than a potential of the first power source line.

According to a third aspect of embodiments, an integrated circuit includes: a plurality of processing circuits; and a plurality of regulators that supply a power source voltage to each of the plurality of processing circuits, wherein each of the plurality of regulators includes: a transistor one of nodes of which is connected to a power source line and the other node of which is connected to an output node from which the power source voltage is output; and an ESD protection circuit that temporarily brings the transistor into conduction when a surge voltage is applied to the power source line.

The object and advantages of the embodiments will be realized and attained by means of the elements and combination particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a diagram illustrating a circuit configuration of a linear regulator;

FIG. 2 is a diagram illustrating a circuit configuration of a switching regulator;

FIG. 3 is a circuit diagram of a circuit example in which an ESD protection circuit is provided in a linear regulator;

FIG. 4 is a circuit diagram of a circuit example in which the ESD protection circuit is provided in the switching regulator;

FIG. 5A is a diagram illustrating a circuit diagram of a linear regulator (power source circuit) of a first embodiment;

FIG. 5B is a diagram illustrating a sectional portion of a P-type MOS transistor in the linear regulator of the first embodiment;

FIG. 6A is a diagram illustrating a circuit diagram of a linear regulator (power source circuit) of a second embodiment;

FIG. 6B is a diagram illustrating a sectional portion of a P-type MOS transistor in the linear regulator of the second embodiment;

FIG. 7A is a circuit diagram illustrating a configuration of a linear regulator (power source circuit) of a third embodiment;

FIG. 7B is an operation waveform diagram of the linear regulator of the third embodiment;

FIG. 8A is a circuit diagram explaining the case where a negative surge voltage is applied to the high potential side power source line VCC in the linear regulator of the third embodiment;

FIG. 8B is a diagram illustrating the sectional portion of the PMOS transistor explaining the case where a negative surge voltage is applied to the high potential side power source line VCC in the linear regulator of the third embodiment;

FIG. 9A is a diagram illustrating a circuit diagram of a switching regulator (power source circuit) of a fourth embodiment;

FIG. 9B is a diagram illustrating a sectional portion of a P-type MOS transistor in the switching regulator of the fourth embodiment;

FIG. 10A is a diagram illustrating a circuit diagram of a switching regulator (power source circuit) of a fifth embodiment;

FIG. 10B is a diagram illustrating a sectional portion of a P-type MOS transistor in the switching regulator of the fifth embodiment;

FIG. 11 is a diagram illustrating a circuit diagram of a switching regulator (power source circuit) of a sixth embodiment;

FIG. 12A is a diagram illustrating a general configuration example of an SoC; and

FIG. 12B is a diagram illustrating a configuration example in which the linear regulators of the first to third embodiments and the switching regulator of the fourth to sixth embodiments are mounted.

### DESCRIPTION OF EMBODIMENTS

Before explaining data holding circuits of the embodiments, a general data holding circuit will be explained.

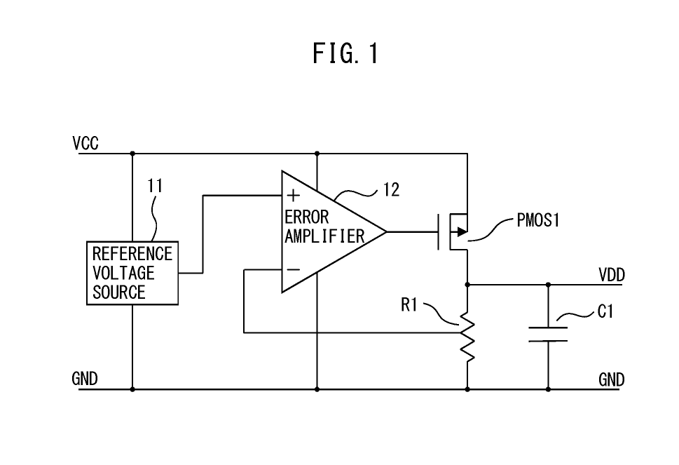

FIG. 1 is a diagram illustrating a circuit configuration of a linear regulator.

A base power source that is supplied to a linear regulator is a power source with less ripples and good voltage stability. The linear regulator in FIG. 1 is a step-down power source circuit also referred to as an LDO (Low Drop Out) and has a reference voltage source 11, an error amplifier 12, a PMOS transistor PMOS1, a resistor R1, and a capacitance element C1. PMOS1 is connected between a high potential side power source line of the base power source that supplies a voltage VCC and an output line that outputs an output voltage VDD, and steps down VCC to VDD, and VDD changes in accordance with the resistance value of PMOS1. In the following explanation, there is a case where a power source line that supplies the voltage VCC is referred to as VCC, an output line that outputs the output voltage VDD is referred to as VDD, and a low potential side power source line having a potential lower than the voltage VCC and the output voltage VDD is referred to as GND.

The resistor R1 and the capacitance element C1 are connected in parallel between VDD and GND. In other words, PMOS1 and R1 are connected in series between VCC and GND. The reference voltage source 11 is a circuit that is connected between VCC and GND and generates a reference voltage by a band gap reference or the like. The error amplifier 12 generates a control signal that is applied to the gate of PMOS1 by comparing the voltage in a specific position of the resistor R1 with the reference voltage. In accordance with the control signal, the resistance value of PMOS1 changes. The voltage in the specific position of the resistor R1 has a voltage value that is obtained by dividing the voltage between VDD and GND by a resistor and is proportional to VDD. The error amplifier 12 generates the control signal so that the difference between the voltage and the reference voltage becomes zero, and therefore, VDD becomes a desired voltage at all times. The capacitance element C1 is provided in order to stabilize VDD. The linear regulator is widely known, and therefore, more explanation is omitted.

As described above, the linear regulator is a circuit that steps down VCC to VDD by the resistance component of PMOS1 and if VCC is a power source with good voltage stability, the voltage stability of VDD is also good, but power is consumed by the resistance component of PMOS1, and therefore, efficiency is low. Because of this, the linear regulator is used as a regulator of an analog circuit, a high-speed interface circuit, etc., whose power consumption is comparatively small but for which high voltage stability is required. In the case where the linear regulator in FIG. 1 is mounted on an integrated circuit chip, it is common to connect the capacitance element C1 to the terminal of the IC chip as an external discrete part, but there is also a case where the capacitance element C1 is mounted on the chip.

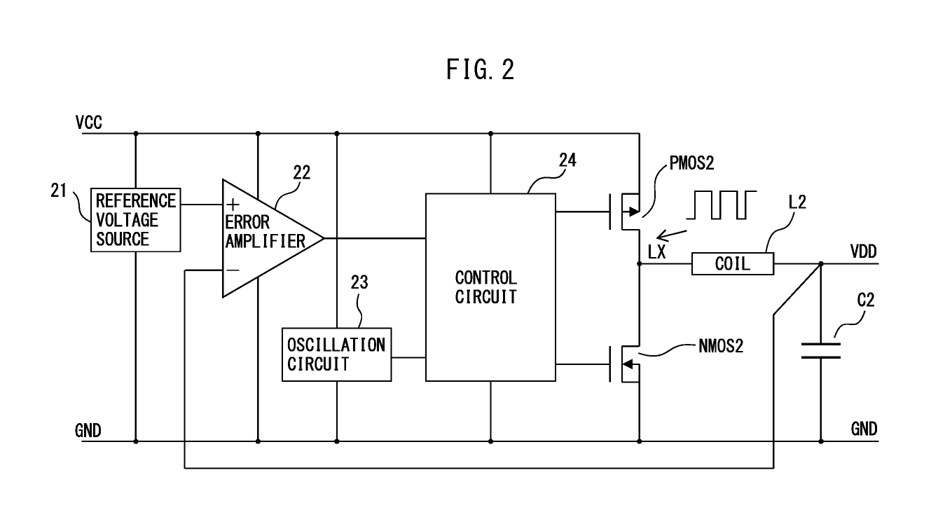

FIG. 2 is a diagram illustrating a circuit configuration of a switching regulator.

The switching regulator has a reference voltage source 21, an error amplifier 22, an oscillation circuit 23, a control circuit 24, a PMOS transistor PMOS2, an NMOS transistor NMOS2, a coil (inductance element) L2, and a capacitance element C2. PMOS2 and NMOS2 are connected in series between VCC and GND and to the gates, a switching signal from the control circuit 24 is applied and PMOS2 and NMOS2 turn on and off in accordance with the switching signal. A connection node LX of PMOS2 and NMOS2 is connected to VDD via the coil L2. The capacitance element C2 is connected between VDD and GND.

The reference voltage source 21 generates a reference voltage like the reference voltage source 11 in FIG. 1. The error amplifier 22 outputs an error signal in accordance with a difference voltage between VDD and the reference voltage to the control circuit 24. The oscillation circuit 23 generates an oscillation signal and outputs the oscillation signal to the control circuit 24. The control circuit 24 generates a switching signal corresponding to the oscillation signal and applies the switching signal to the gates of PMOS2 and NMOS2. The control circuit 24 changes the duty ratio of the switching signal in accordance with the error signal. Due to this, VDD is controlled so as to be in a predetermined voltage ratio with respect to the reference voltage. The switching regulator is widely known, and therefore, more explanation is omitted. In the case where the switching regulator in FIG. 2 is mounted on the integrated circuit (IC) chip, it is common to connect the coil L2 and the capacitance element C2 to the terminal of the IC chip as external discrete parts, but there is also a case where the coil L2 and the capacitance element 2 are mounted on the chip.

The efficiency of the switching regulator is higher than that of the linear regulator because a loss due to the resistance component is less, but the voltage stability is lower than that of the linear regulator because ripples accompanying switching are generated in VDD. Because of this, the switching regulator is used as a regulator of a CPU core logic circuit or the like whose power consumption is large and for which high voltage stability is not required.

As described previously, in the power source line, the ESD (Electro-Static Discharge) protection circuit for protecting the circuit from a surge voltage due to static electricity is provided.

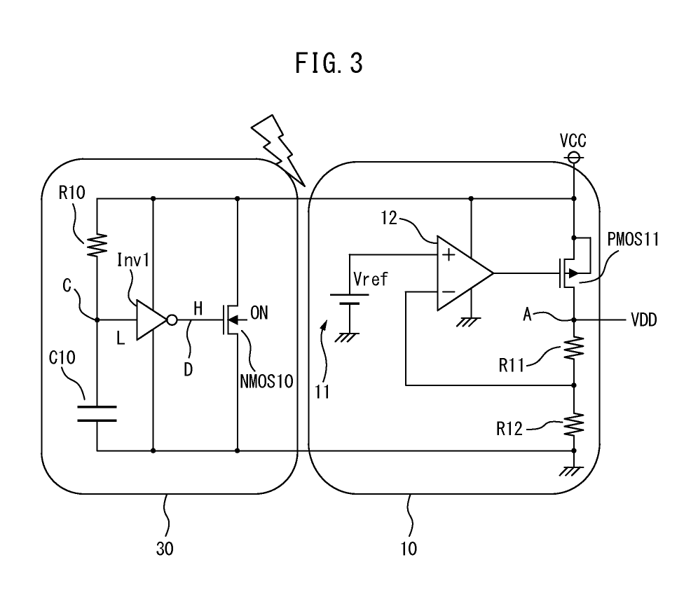

FIG. 3 is a circuit diagram of a circuit example in which an ESD protection circuit is provided in a linear regulator.

As illustrated in FIG. 3, an ESD protection circuit 30 is connected to the power source lines VCC and GND of a linear regulator 10. The ESD protection circuit 30 has a resistor R10 and a capacitance element C10 connected in series between VCC and GND, an inverter Inv1 that uses VCC and GND as a power source, and an NMOS transistor NMOS10 connected between VCC and GND. A connection node (C point) of R10 and C10 is connected to the input of Inv1 and the output of Inv1 is connected to the gate of NMOS10.

The linear regulator (LDO) 10 has the same configuration as that of the linear regulator in FIG. 1, but the display of the reference voltage source 11 is changed and the resistor R1 is replaced with two resistors R11 and R12 connected in series. The schematic representation of the external capacitance element C1 is omitted. The resistance values of the resistors R11 and R12 are determined appropriately in accordance with a ratio between the output voltage VDD and a reference voltage Vref.

In the normal state of the ESD protection circuit 30, the voltage of the C point is VCC, the output (voltage of a D point) of Inv1 is the L level, and NMOS10 is in the turned-off state. This is the same also in the case where VCC increases gradually when the power source is turned on and NMOS10 is in the turned-off state. If a positive surge voltage is applied to VCC in the state where the power source VCC is not applied, VCC increases instantaneously, but an increase in voltage of the C point is delayed due to the resistor R10. The power source of Inv1 is VCC and GND and the increase in voltage of the C point is delayed, and therefore, the input of Inv1 relatively turns to the L level, the output (voltage of the D point) of Inv1 turns to the H level, and NMOS10 turns on. Due to this, VDD and GND are brought into conduction and the voltage of VCC having increased instantaneously drops, and thereby, the surge voltage is absorbed. When the power source is turned on after the application of such a surge voltage, NOMOS10 turns off as described above, and therefore, the normal state is brought about.

On the other hand, if a positive surge voltage is applied to VCC in the state where the power source VCC is applied, as in the above, NMOS10 turns on and the surge voltage is absorbed. After that, if the voltage of VCC increases, current flows to the capacitance element C10 via the resistor R10 and charges C10, and therefore, the voltage of the C point increases. The charging speed is determined by a time constant determined by the resistance value of the resistor R10 and the capacitance value of the capacitance element C10. Further, by NMOS10 turning on, the increased voltage of VDD also drops, and therefore, the input of Inv1 relatively turns to the H level, the level of the D point turns to L, and NMOS10 turns off, and thereby, the original state is returned. As above, the ESD protection circuit 30 protects the linear regulator (LDO) 10 from a surge voltage by absorbing the influence of the surge voltage.

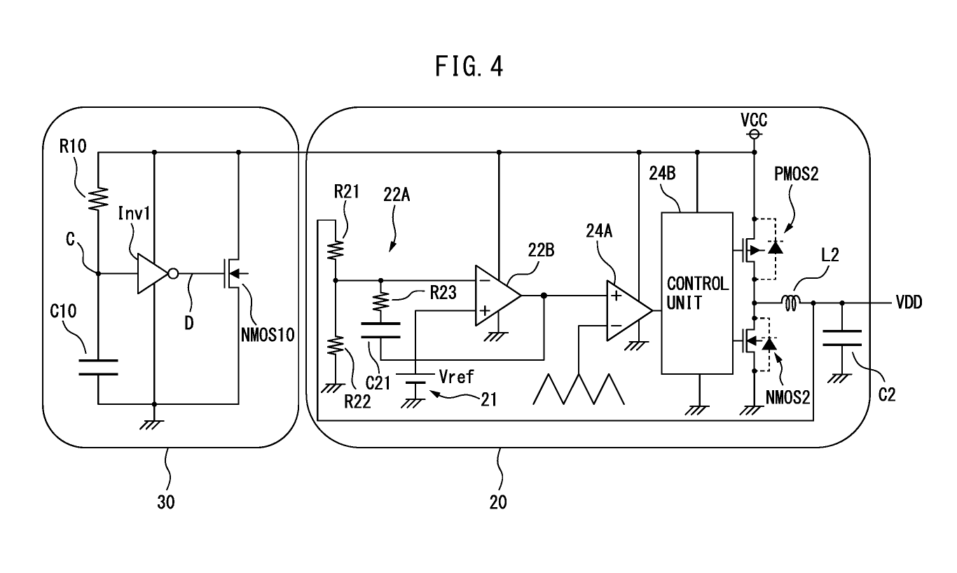

FIG. 4 is a circuit diagram of a circuit example in which the ESD protection circuit is provided in the switching regulator.

As illustrated in FIG. 4, the ESD protection circuit 30 is connected to the power source lines VCC and GND of a switching regulator 20. The ESD protection circuit 30 is the same as that in FIG. 3.

The switching regulator 20 has the same configuration as that of the linear regulator in FIG. 2, but the display of the reference voltage source 21 is changed, the oscillation circuit 23 is not illustrated, and a waveform of an oscillation signal in the shape of a sawtooth that is output is illustrated. The error amplifier 22 in FIG. 2 is formed by a portion 22A including resistors R21 to R23 and a capacitance element C21, and an amplifier 22B. R21 and R22 generate a voltage obtained by dividing VDD by a resistor. The amplifier 22B compares the voltage divided by a resistor with the reference voltage Vref and outputs an error signal (difference voltage). R23 and C21 are connected in series between the input and output of the amplifier 22B and stably perform a comparison between VDD including ripples and Vref and prevent an oscillation of the circuit. The control circuit 24 in FIG. 2 is formed by a PWM amplifier 24A and a control unit 24B. The PWM amplifier 24A compares the error signal and the oscillation signal and generates a PWM (Pulse Width Modulation) signal. The control unit 24B converts the PWM signal into a switching signal that is applied to PMOS2 and NMOS2. PMOS2 and NMOS2 are illustrated with a parasitic diode included and the display of the coil L2 is also changed.

The ESD protection circuit illustrated in FIG. 3 and FIG. 4 cause a large current to flow if transiently, and therefore, the size of NMOS10 is increased. Because of this, the area of the ESD protection circuit 30 increases. The influence of this problem is great in the case where the ESD circuit is mounted on an IC chip and the ratio of the area of the ESD protection circuit to the total area of the chip becomes high.

In the embodiment explained below, a power source circuit having an ESD protection circuit with a small area is disclosed.

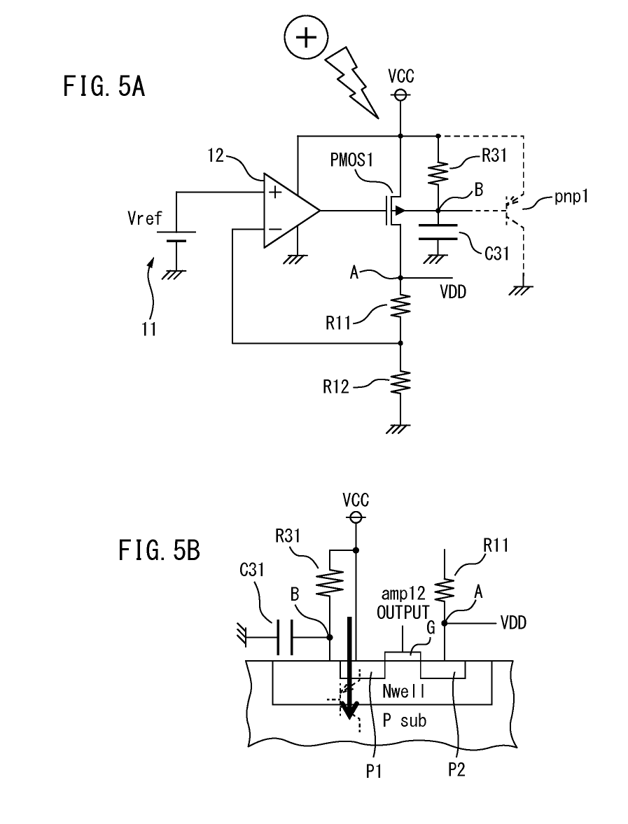

FIG. 5A and FIG. 5B are diagrams illustrating the configuration of the linear regulator (power source circuit) of the first embodiment, and FIG. 5A is a circuit diagram and FIG. 5B is a diagram illustrating the sectional portion of the P-type MOS transistor.

As illustrated in FIG. 5A, the linear regulator of the first embodiment has the P-type MOS transistor PMOS1, the resistors R11 and R12, the reference voltage source 11, the error amplifier 12, a resistor R31, and a capacitance element C31.

PMOS1 and the resistors R11 and R12 are connected in series between VCC and GND. A connection node (A point) of PMOS1 and R11 is the output node and when in use, the capacitance element C1 (not illustrated) in FIG. 1 is connected to the output node and the output voltage VDD is output from the output node. The error amplifier 12 compares the voltage of the connection node of R11 and R12 with the reference voltage Vref that the reference voltage source 11 outputs, generates a control signal in accordance with an error signal (difference voltage), and applies the control signal to the gate of PMOS1. The above configuration is the same as that of the linear regulator in FIG. 1 and FIG. 3.

The linear regulator of the first embodiment differs from the linear regulator in FIG. 1 and FIG. 3 in that the resistor R31 is connected between the high potential side power source line VCC and the back gate of PMOS1, and the capacitance element C31 is connected between the back gate of PMOS1 and the low potential side power source line GND.

As illustrated in FIG. 5B, an N well (Nwell) is formed on a P-type substrate (Psub), in the N well, P-type regions P1 and P2 are formed, and on a channel region between P1 and P2, a gate electrode G is formed. The gate electrode G is connected to the output of the error amplifier 12, the P-type region P1 is connected to the power source line VCC, the P-type region P2 is connected to the output line VDD, the N well is connected to VCC via the resistor R31, and the capacitance element 31 is connected between the N well and GND. The P-type substrate is connected to GND. Due to this, the P-type region P1, the N well, and the P-type substrate form a PNP-type parasitic transistor pnp1 as indicated by a broken line.

In the linear regulator of the first embodiment, in the normal state, the voltage of a B point is VCC and to the back gate of PMOS1, VCC is applied. This state is the same as the state in FIG. 1 and FIG. 3 and as explained in FIG. 1 and FIG. 3, the linear regulator operates as the step-down power source circuit (LDO). This is also the same in the case where VCC increases gradually when the power source is turned on.

If a positive surge voltage is applied to VCC in the state where the power source VCC is not applied, VCC increases instantaneously, a current that charges the capacitance element C31 flows through the resistor R31, a difference in voltage occurs between VCC and the B point, and a current is generated between the emitter and base of the parasitic transistor pnp1. Due to this current, pnp1 turns on, a current flows between the emitter and collector, i.e., between the high potential side power source line VCC and the low potential side power source line GND, the voltage of VCC drops, and thereby, the surge voltage is absorbed. When the power source is turned on after the application of such a surge voltage, the voltage of the B point becomes VCC as described above, and therefore, the normal state is brought about.

If a positive surge voltage is applied to VCC in the state where the power source VCC is applied, as in the above, a difference in voltage occurs between VCC and the B point, pnp1 turns on, and thereby, the surge voltage is absorbed. At the same time, if the voltage of VCC increases, current flows to the capacitance element C31 via the resistor R31 and charges C31, and the voltage of the B point increases. The charging speed is determined by a time constant determined by the resistance value of the resistor R31 and the capacitance value of the capacitance element C31. Further, when pnp1 turns on, the increased voltage of VDD also drops, and therefore, the level of the B point becomes close to VCC, pnp1 turns off, and the normal operation state is returned. The linear regulator of the first embodiment prevents VCC from increasing considerably by absorbing the influence of the surge voltage as described above. In other words, the linear regulator of the first embodiment implements the ESD protection circuit by making use of PMOS1 and adding R31 and C31.

Consequently, it is not necessary to separately provide the ESD protection circuit 30 as in FIG. 3, and therefore, it is possible to reduce the size of the circuit by the amount corresponding to the area of NMOS10 with a large area included in the ESD protection circuit 30.

In the above-described explanation, the case is explained where a positive surge voltage is applied to VCC, and the case where a negative surge voltage is applied to VCC will be described later.

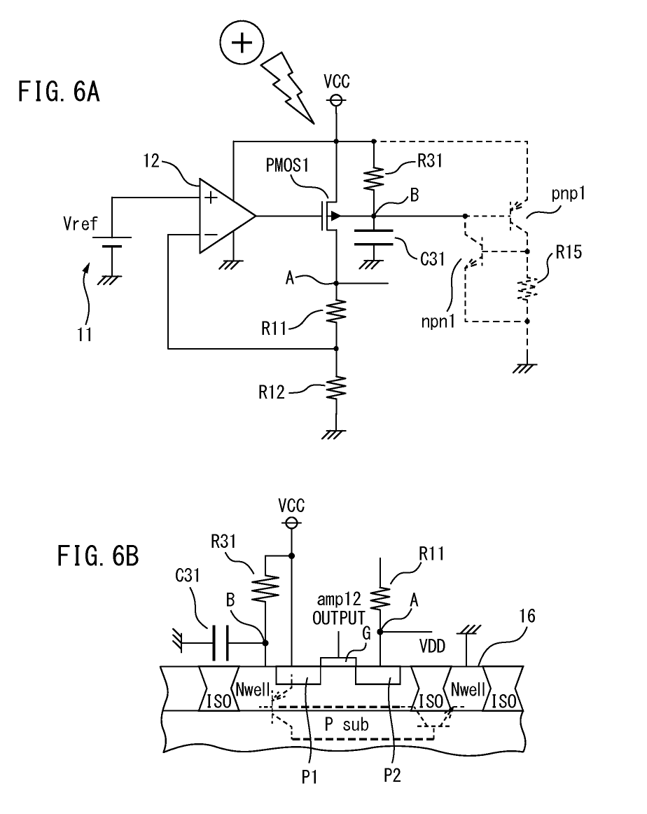

FIG. 6A and FIG. 6B are diagrams illustrating a configuration of a linear regulator (power source circuit) of a second embodiment, and FIG. 6A is a circuit diagram and FIG. 6B illustrates the sectional portion of the P-type MOS transistor.

As illustrated in FIG. 6B, in the linear regulator of the second embodiment, an element isolation region ISO is provided around the N well (Nwell) in which the P-type MOS transistor PMOS1 is formed. Further, the element isolation region ISO is also provided around at least part of an N well (Nwell) 16 around the element isolation region ISO and the N well (Nwell) 16 of this portion is connected to GND. The above is different from the first embodiment. The N well 16 that is formed by further isolating at least part of the N well by the element isolation region ISO, which is isolated from the N well in which the P-type MOS transistor PMOS1 is formed by the element isolation region ISO, and by fixing the potential of the isolated N well is referred to as an N well guard ring.

With the above structure, a parasitic transistor npn1 is formed between the B point and GND by the N well, the P-type substrate (Psub), and the N well (Nwell) 16 as indicated by a broken line. A resistor R15 is a resistance component between the P-type substrate and GND.

As illustrated in FIG. 6A, the parasitic transistors pnp1 and npn1 form a thyristor structure by the connection relationship therebetween and it is possible to cause a large current to flow by the thyristor operation.

In the linear regulator of the first embodiment, by turning on the parasitic transistor pnp1, the surge voltage of VCC is discharged to GND, but the parasitic transistor pnp1 has a small amplification factor hfe and is not large enough to discharge the surge voltage in a brief time. In order for the linear regulator to resist a large surge voltage, it is required to increase the size of the parasitic transistor pnp1, i.e., to increase the size of PMOS1.

In contrast to this, in the linear regulator of the second embodiment, it is possible to cause a large current to flow by the thyristor operation, and therefore, it is not necessary to increase the size of PMOS1.

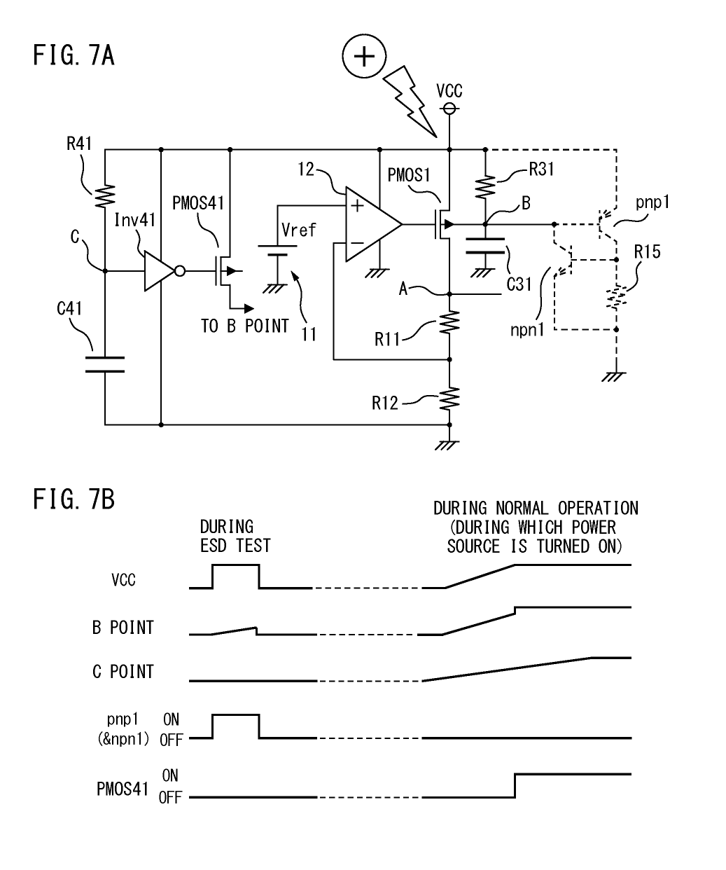

FIG. 7A and FIG. 7B are diagrams illustrating a configuration of a linear regulator (power source circuit) of a third embodiment, and FIG. 7A is a circuit diagram and FIG. 7B is an operation waveform diagram.

As illustrated in FIG. 7A, the linear regulator of the third embodiment differs from the linear regulator of the second embodiment in that a latch-up recovery circuit including a resistor R41, a capacitance element C41, and inverter Inv41, and a P-type MOS transistor PMOS41 is attached. The drain of PMOS41 of the latch-up recovery circuit is connected to the B point. The latch-up recovery circuit differs from the ESD protection circuit in FIG. 3 in that the transistor is PMOS, the time constant of the time constant circuit of the resistor R41 and the capacitance element C41 is sufficiently longer than the time constant of the time constant circuit of R10 and C10 (and R31 and C31). Further, the amount of current that PMOS41 can cause to flow may be considerably smaller than that of NMOS10 in FIG. 3 and the size of PMOS41 is sufficiently small.

During the normal operation during which VCC is applied, the C point is the H level, PMOS41 is in the turned-on (ON) state, the drain of PMOS41 outputs VCC, and this is applied to the B point at VCC.

As illustrated during the ESD test in FIG. 7B, in the state where the power source is not applied, the voltage of the B point and the C point is the GND level, pnp1 and npn1 are in the turned-off (OFF) state, and PMOS41 is in the turned-off state. In this state, if a high voltage (surge voltage) for the ESD test is applied to VCC for a short time, the voltage of the B point increases and pnp1 and npn1 turn on (ON), but the C point remains at GND because the time constant is long and PMOS41 remains in the turned-off state. When the application of a high voltage to VCC stops and VCC returns to GND, pnp1 and npn1 turn off again. In this manner, the circuit is protected by discharging the surge voltage to GND.

As illustrated during the normal operation (during which the power source is turned on) in FIG. 7B, when the power source is turned on, VCC increases gradually and the voltage of the B point also increases gradually. The voltage of the C point increases delayed from that of the B point because of the long time constant and when the voltage of the C point exceeds the threshold value of the inverter Inv41, the output of Inv41 turns to the L level and PMOS41 turns on. Due to this, the voltage of the drain of PMOS41 becomes VCC and the voltage of the B point also becomes VCC. On the other hand, the voltage of the C point increases up to VCC. As described above, it is unlikely that pnp1 and npn1 turn on when the power source is turned on. As described above, even in the case where the surge voltage is applied during the ESD test and pnp1 and npn1 turn off after turning on once, it is also unlikely that pnp1 and npn1 turn on when the power source is turned on.

During the normal operation during which VCC is supplied, if a surge voltage is applied to the power source line VCC, as described above, the voltage of the B point increases, pnp1 and npn1 turn on, and a large current resulting from the surge voltage is discharged to GND by the thyristor structure. When the thyristor structure turns on once, the thyristor structure enters the latch-up state where the on state is maintained even if VCC drops. On the other hand, the voltage of the C point increases gradually because the time constant determined by R41 and C41 is long, and exceeds the threshold value of Inv41, and the output of Inv41 turns to the L level, and PMOS41 turns on. Due to this, the B point enters the state of being connected to VCC and pnp1 turns off, and therefore, npn1 also turns off. In this manner, the thyristor structure in the latch-up state is turned off forcibly.

As explained above, in the linear regulator of the third embodiment, the thyristor structure formed by two parasitic transistors is forcibly turned off even if the thyristor structure latches up due to the application of a surge voltage. Due to this, it is possible for the thyristor structure to turn on only when absorbing a surge voltage and to prevent the destruction of the element (PMOS1) caused by an overcurrent due to the latch-up state continuing to flow.

In the first to third embodiments, the case is explained where a positive surge voltage is applied to the high potential side power source line VCC, but there may be a case where a negative surge voltage is applied to the high potential side power source line VCC. That the linear regulators in the first to third embodiments will operate normally even in such a case is explained by taking the third embodiment as an example.

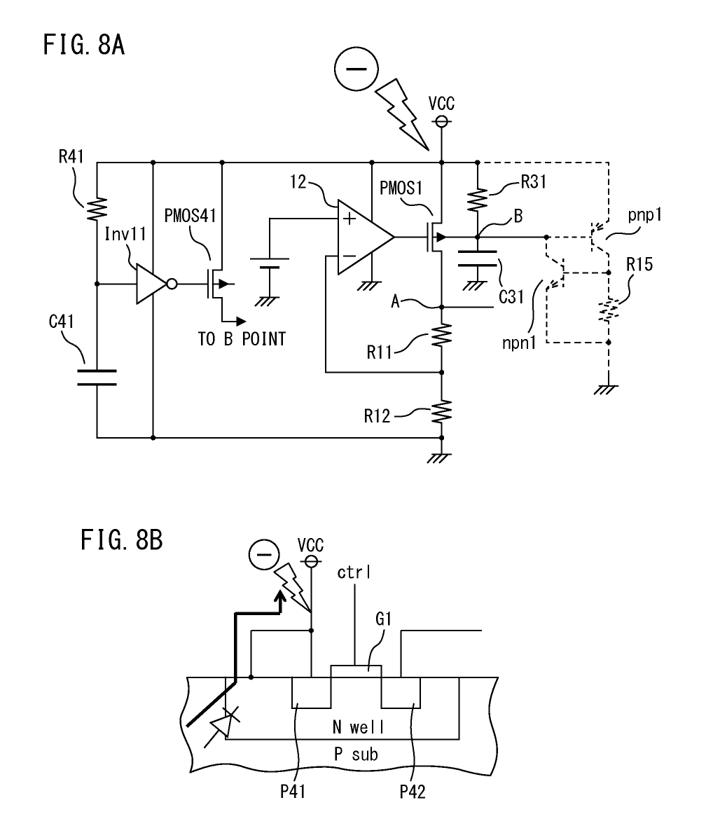

FIG. 8A and FIG. 8B are diagrams explaining the case where a negative surge voltage is applied to the high potential side power source line VCC in the linear regulator of the third embodiment, and FIG. 8A is a circuit diagram and FIG. 8B illustrates the sectional portion of the PMOS transistor.

FIG. 8A is the same as FIG. 7A, but differs from that in illustrating the way a negative surge voltage is applied to the high potential side power source line VCC.

FIG. 8B illustrates the sectional portion of the PMOS transistor and a large number of PMOS transistors having such a structure exist within the circuit, such as within NMOS41 and the inverter Inv11, not limited to PMOS1. For example, if NMOS41 is taken as an example, the P region indicated by P41 corresponds to the source region, the P region indicated by P42 to the drain region, and G1 to the gate, respectively, and the P region indicated by P41 is connected to VCC and the P region indicated by P42 is connected to the B point. The N well is connected to VCC and Psub is connected to GND. Here, if a negative surge voltage is applied to VCC, Psub and the N well form a PN junction diode, and therefore, a current flows to VCC at a low potential through the PN junction diode from GND at a high potential, and thereby, the negative surge voltage is discharged. Consequently, it is unlikely that the element that forms the circuit is destroyed. This is also the same in the first and second embodiments and is also the same in fourth to sixth embodiments, to be explained later.

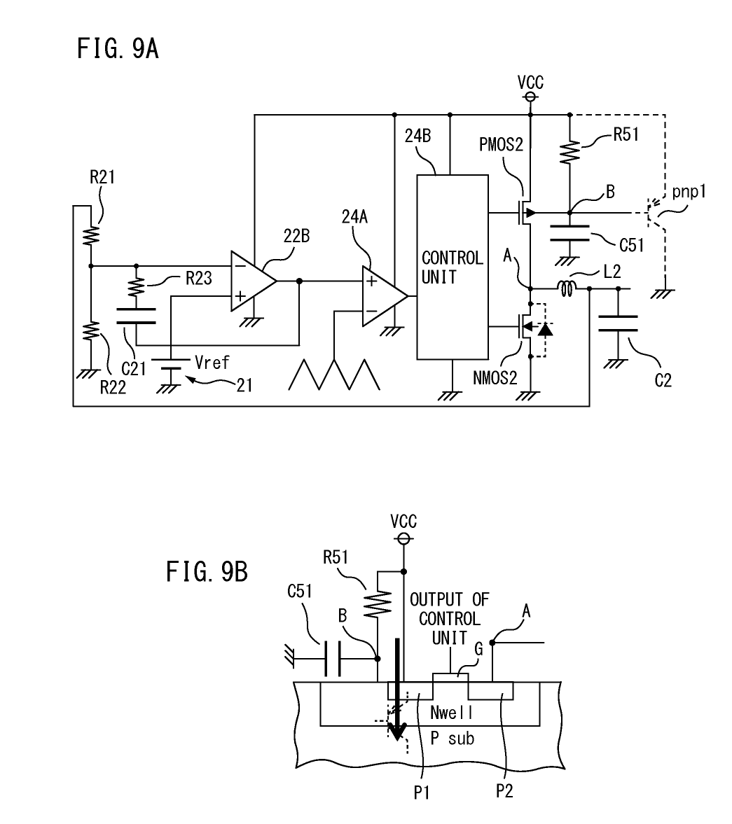

FIG. 9A and FIG. 9B are diagrams illustrating a configuration of a switching regulator (power source circuit) of a fourth embodiment, and FIG. 9A is a circuit diagram and FIG. 9B is a diagram illustrating the sectional portion of the P-type MOS transistor.

The switching regulator of the fourth embodiment has the portion 22A including the reference voltage source 21, the resistors R21 to R23, and the capacitance element C21, the amplifier 22B, the PWM amplifier 24A, and the control unit 24B. The switching regulator of the fourth embodiment further has the PMOS transistor PMOS2, the NMOS transistor NMOS2, the coil (inductance element) L2, and the capacitance element C2. The above configuration is the same as that of the switching regulator 20 illustrated in FIG. 4.

The switching regulator of the fourth embodiment has a resistor R51 connected between the high potential side power source line VCC and the back gate of PMOS2, and a capacitance element C51 connected between the back gate of PMOS2 and the low potential side power source line GND.

The operations of the portions except for the resistor R51 and the capacitance element C51 are the same as those of the switching regulator 20 in FIG. 4, and therefore, explanation is omitted.

In the fourth embodiment, PMOS2 of the switching regulator has an element structure as illustrated in FIG. 9B and by providing the resistor R51 and the capacitance element C51 as explained in the first embodiment, the parasitic transistor pnp1 is formed.

In the normal state, the voltage of the B point is VCC and to the back gate of PMOS2, VCC is applied. This is the same as the state in FIG. 2 and FIG. 4 and PMOS2 performs the turning-on/off operation in accordance with the switching signal. This is also the same in the case where VCC increases gradually when the power source is turned on.

If a positive surge voltage is applied to VCC in the state where the power source VCC is not applied, VCC increases instantaneously, a current that charges the capacitance element C51 flows through the resistor R51, a difference in voltage between VCC and the B point occurs, and a current is generated between the emitter and base of pnp1. Due to this current, pnp1 turns on, a current flows between the emitter and collector, i.e., between the high potential side power source line VCC and the low potential side power source line GND, the voltage of VCC drops, and thereby, the surge voltage is absorbed. When the power source is turned on after the application of such a surge voltage, as described above, the voltage of the B point becomes VCC, and therefore, the normal state is brought about.

If a positive surge voltage is applied to VCC in the state where the power source VCC is applied, as in the above, a difference in voltage between VCC and the B point occurs, the pnp transistor turns on, and thereby, the surge voltage is absorbed. At the same time, after it is determined by the time constant determined by the resistance value of the resistor R51 and the capacitance value of the capacitance element C51, the level of the B point becomes close to VCC, pnp1 turns off, and the normal operation state is returned.

The switching regulator of the fourth embodiment absorbs the influence of a surge voltage as above and prevents VCC from increasing considerably. In other words, the switching regulator of the fourth embodiment implements the ESD protection circuit by making use of PMOS2 and adding R51 and C51.

Consequently, it is not necessary to separately provide the ESD protection circuit 30 as in FIG. 4, and therefore, it is possible to reduce the size of the circuit by the amount corresponding to the area of NMOS10 with a large area included in the ESD protection circuit 30.

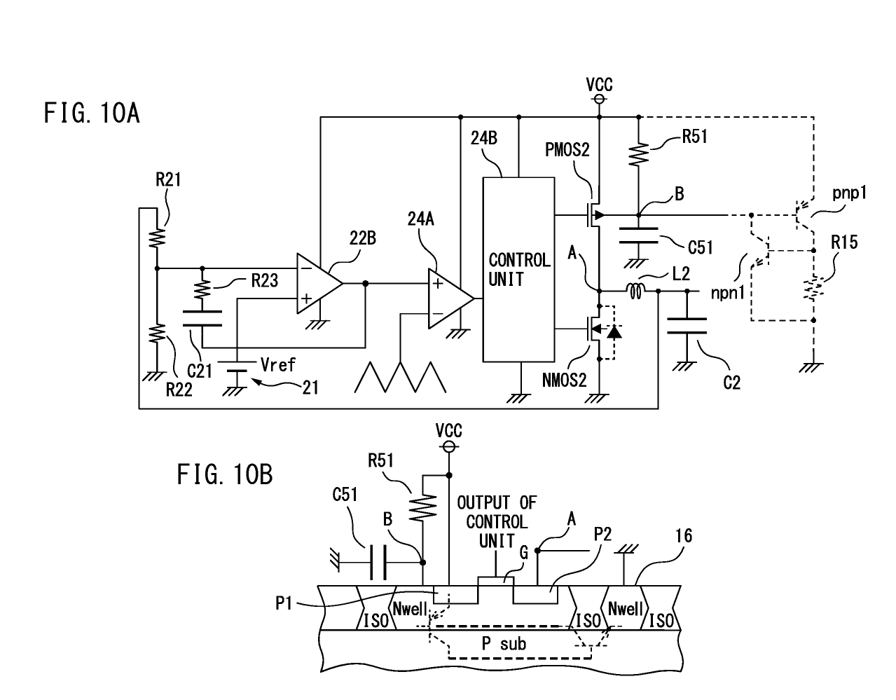

FIG. 10A and FIG. 10B are diagrams illustrating a configuration of a switching regulator (power source circuit) of a fifth embodiment, and FIG. 10A is a circuit diagram and FIG. 10B illustrates the sectional portion of the P-type MOS transistor.

The switching regulator of the fifth embodiment has the same circuit configuration as that of the fourth embodiment. However, in the fifth embodiment, as in the second embodiment, the guard ring ISO is provided around the N well (Nwell) in which PMOS2 is formed and the guard ring ISO is also provided around at least part of the N well (Nwell) around the guard ring ISO. In other words, the N well guard ring is formed in PMOS2.

The switching regulator of the fifth embodiment implements the ESD protection circuit having a thyristor structure by the parasitic transistors pnp1 and npn1 by making use of PMOS2, adding R51 and C51, and forming the N well guard ring in PMOS2.

The operation as the switching regulator is the same as that of the switching regulator of the first embodiment in FIG. 2 and FIG. 4. The function and operation of the ESD protection circuit having the thyristor structure are the same as those of the second embodiment. A further explanation is omitted.

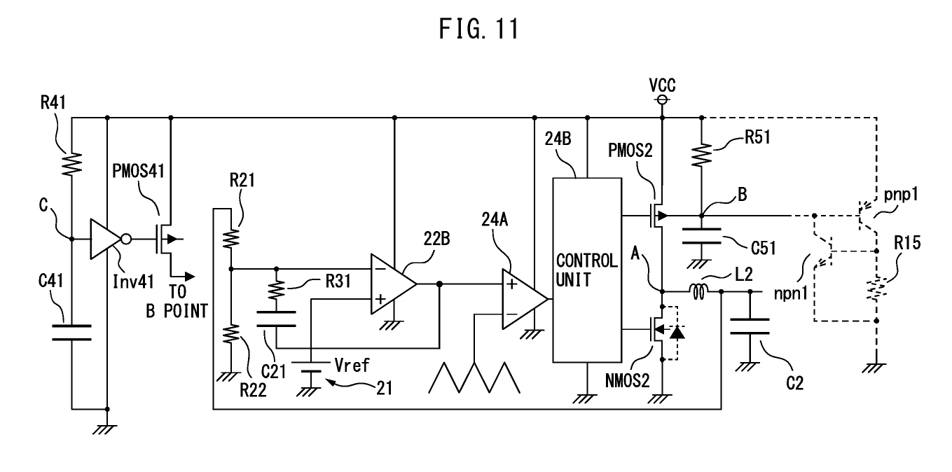

FIG. 11 is a diagram illustrating a circuit diagram of a switching regulator (power source circuit) of a sixth embodiment.

The switching regulator of the sixth embodiment differs from the linear regulator of the fifth embodiment in that a latch-up recovery circuit including the resistor R41, the capacitance element C41, the inverter Inv41, and the P-type MOS transistor PMOS41 is added.

The configuration and operation of the latch-up recovery circuit are the same as those of the third embodiment and it is possible to prevent the destruction of the element (PMOS2) caused by an overcurrent due to the latch-up state continuing to flow by forcibly turning off the thyristor structure even if it latches up due to the application of a surge voltage.

As above, the first to sixth embodiments are explained and next, an example of the SoC that uses the linear regulator of the first to third embodiments and the switching regulator of the fourth to sixth embodiments is explained.

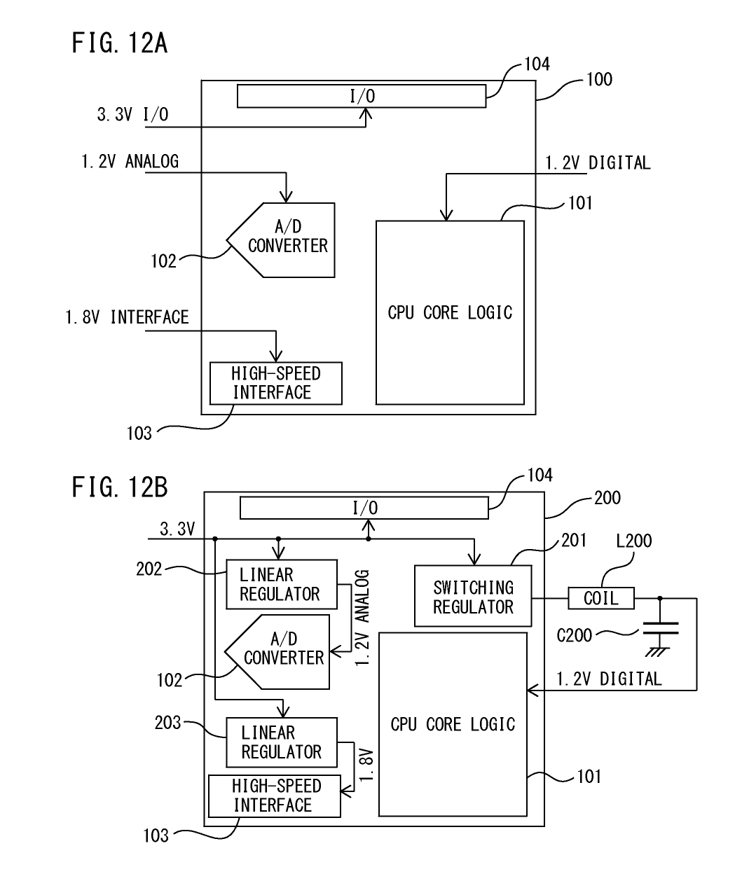

FIG. 12A and FIG. 12B are diagrams illustrating configuration examples of the SoC, and FIG. 12A illustrates a general configuration example and FIG. 12B illustrates a configuration example in which the linear regulators of the first to third embodiments and the switching regulator of the fourth to sixth embodiments are mounted.

As illustrated in FIG. 12A, an SoC 100 has a plurality of circuit portions whose specifications of the power sources that are supplied are different. In FIG. 12A, the SoC 100 has a CPU core logic circuit 101, an A/D converter 102, a high-speed interface circuit 103, and an I/O circuit 104. The CPU core logic circuit 101 accepts low voltage stability, but operates on a 1.2 V digital power source whose amount of current is large. The A/D converter 102 operates on a 1.2 V analog power source with less ripples and high voltage stability. The high-speed interface circuit 103 operates on a 1.8 V interface power source with high voltage stability because of the communication destination. The I/O circuit 104 operates on a 3.3 V I/O power source with high voltage stability. The general SoC 100 does not have a power source circuit, but has input terminals of the 1.2V digital power source, the 1.2 V analog power source, the 1.8 V interface power source, and the 3.3 V I/O power source, all of these being necessary for the operations of the mounted circuits, and the power source of each circuit is supplied from the outside through the input terminal. In order to implement such a configuration, power source circuits that generate these power sources are provided outside, and are routed up to the SoC terminals.

As a result, the number of power source terminals and the number of kinds of power source terminals that are provided in the SoC increase, and therefore, the number of pins increases, and that the wiring of the power sources from the external power source circuits up to the SoC becomes complicated.

Consequently, as illustrated in FIG. 12B, only the 3.3 V power source is supplied from the outside and inside an SoC 200, from the 3.3 V power source, the 1.2 V digital power source, the 1.2 V analog power source, and the 1.8 V interface power source are generated. To this end, the SoC 200 mounts a switching regulator 201 that generates the 1.2 V digital power source and two linear regulators 202 and 203 that generate the 1.2 V analog power source and the 1.8 V interface power source. To the I/O circuit 104, the 3.3 V I/O power source that is supplied from the outside is supplied as it is. Further, a coil L200 having a comparatively large inductance and a capacitance element C200 having a comparatively large capacitance value that are used by the switching regulator 201 are connected to the SoC 200 as discrete parts.

In the case where the ESD protection circuit 30 illustrated in FIG. 3 and FIG. 4 is provided, the ESD protection circuit 30 is provided in the vicinity of the 3.3 V power source terminal of the SoC 200. As described previously, the ESD protection circuit 30 illustrated in FIG. 3 and FIG. 4 uses an NMOS transistor large in size, and therefore, the chip area of the SoC 200 increases accordingly.

In contrast, if the switching regulator 201 is implemented by the switching regulator of the fourth to sixth embodiments and the linear regulators 202 and 203 are implemented by the linear regulator of the first to third embodiments, it is not necessary to separately provide the ESD protection circuit. Therefore, it is possible to suppress an increase in the chip area of the SoC 200.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a illustrating of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A power source circuit comprising:
a P-type transistor one of a source and a drain of which is connected to a first power source line and the other of the source and the drain of which is connected to an output node;
a resistor connected between a back gate of the P-type transistor and the first power source line; and
a capacitance element connected to the back gate of the P-type transistor and to a second power source line having a potential lower than a potential of the first power source line.

2. The power source circuit according to claim 1, wherein
the P-type transistor is formed in an N well formed in a P-type region, and
the source or the drain of the P-type transistor, the N well, and the P-type region constitute a PNP-type transistor.

3. The power source circuit according to claim 2, further comprising:
an N well guard ring provided around the N well in which the P-type transistor is formed.

4. The power source circuit according to claim 3, wherein
the N well guard ring, the P-type region, and the N well constitute an NPN-type transistor, and
the PNP-type transistor and the NPN-type transistor constitute a thyristor.

5. The power source circuit according to claim 1, further comprising:
a latch-up recovery circuit connected to the first power source line and the second power source line, output of which is at the potential of the first power source line during a normal time, becomes high impedance when a positive surge voltage is applied to the first power source line, and further becomes the potential of the first power source line again after a period of time longer than a time constant determined by the resistor and the capacitance element.

6. The power source circuit according to claim 4, further comprising:
a latch-up recovery circuit connected to the first power source line and the second power source line, output of which is at the potential of the first power source line during a normal time, becomes high impedance when a positive surge voltage is applied to the first power source line, and further becomes the potential of the first power source line again after a period of time longer than a time constant determined by the resistor and the capacitance element.

7. The power source circuit according to claim 1, further comprising:
an output resistor connected between the P-type transistor and the second power source line;
a reference voltage source that outputs a reference voltage; and
an amplifier that generates a control signal to be applied to a gate of the P-type transistor, wherein the amplifier generates the control signal so that an output voltage from a connection node of the P-type transistor and the output resistor becomes a first voltage with respect to the reference voltage.

8. The power source circuit according to claim 4, further comprising:
an output resistor connected between the P-type transistor and the second power source line;
a reference voltage source that outputs a reference voltage; and
an amplifier that generates a control signal to be applied to a gate of the P-type transistor, wherein
the amplifier generates the control signal so that an output voltage from a connection node of the P-type transistor and the output resistor becomes a first voltage with respect to the reference voltage.

9. The power source circuit according to claim 1, further comprising:
an N-type MOS transistor connected between the P-type MOS transistor and the second power source line;
a reference voltage source that outputs a reference voltage; and
a control circuit that generates a switching signal to be applied to gates of the P-type MOS transistor and the N-type MOS transistor, wherein
the control circuit generates the switching signal so that an output voltage from a connection node of an inductance element connected to the power source circuit and an output capacitance element connected to the inductance element becomes a first voltage with respect to the reference voltage, the inductance element having terminals one of which is connected to a connection node of the P-type MOS transistor and the N-type MOS transistor, the output capacitance element connected between the other terminal of the inductance element and the second power source line.

10. The power source circuit according to claim 4, further comprising:
an N-type MOS transistor connected between the P-type MOS transistor and the second power source line;
a reference voltage source that outputs a reference voltage; and
a control circuit that generates a switching signal to be applied to gates of the P-type MOS transistor and the N-type MOS transistor, wherein
the control circuit generates the switching signal so that an output voltage from a connection node of an inductance element connected to the power source circuit and an output capacitance element connected to the inductance element becomes a first voltage with respect to the reference voltage, the inductance element having terminals one of which is connected to a connection node of the P-type MOS transistor and the N-type MOS transistor, the output capacitance element connected between the other terminal of the inductance element and the second power source line.

11. An electronic circuit comprising:
a processing circuit; and
a power source circuit which supplies a power source voltage to the processing circuit, wherein
the power source circuit includes:
a P-type transistor one of a source and a drain of which is connected to a first power source line and the other of the source and the drain of which is connected to an output node;
a resistor connected between a back gate of the P-type transistor and the first power source line; and
a capacitance element connected to the back gate of the P-type transistor and to a second power source line having a potential lower than a potential of the first power source line.

12. The electronic circuit according to claim 11, comprising:
a plurality of processing circuits and a plurality of power source circuits that supply power source voltages to the plurality of processing circuits, wherein
at least part of the power source voltages that the plurality of power source circuits supplies are different voltages.

13. The electronic circuit according to claim 12, wherein
the P-type transistor is formed in an N well formed in a P-type region, and
the source or the drain of the P-type transistor, the N well, and the P-type region constitute a PNP-type transistor.

14. The electronic circuit according to claim 12, wherein the power source circuit further includes:
an N well guard ring provided around the N well in which the P-type transistor is formed.

15. The electronic circuit according to claim 13, wherein
the N well guard ring, the P-type region, and the N well constitute an NPN-type transistor, and
the PNP-type transistor and the NPN-type transistor constitute a thyristor.

16. The electronic circuit according to claim 15, wherein the power source circuit further includes:
a latch-up recovery circuit connected to the first power source line and the second power source line, output of which is at the potential of the first power source line during a normal time, becomes high impedance when a positive surge voltage is applied to the first power source line, and further becomes the potential of the first power source line again after a period of time longer than a time constant determined by the resistor and the capacitance element.

17. The electronic circuit according to claim 11, wherein the power source circuit further includes:
an output resistor connected between the P-type transistor and the second power source line;
a reference voltage source that outputs a reference voltage; and
an amplifier that generates a control signal to be applied to a gate of the P-type transistor, and wherein
the amplifier generates the control signal so that an output voltage from a connection node of the P-type transistor and the output resistor becomes a first voltage with respect to the reference voltage.

18. The electronic circuit according to claim 11, wherein the power source circuit includes:
an N-type MOS transistor connected between the P-type MOS transistor and the second power source line;
a reference voltage source that outputs a reference voltage; and
a control circuit that generates a switching signal to be applied to gates of the P-type MOS transistor and
the N-type MOS transistor, and wherein the control circuit generates the switching signal so that an output voltage from a connection node of an inductance element connected to the power source circuit and an output capacitance element connected to the inductance element becomes a first voltage with respect to the reference voltage, the inductance element having terminals one of which is connected to a connection node of the P-type MOS transistor and the N-type MOS transistor, the output capacitance element connected between the other terminal of the inductance element and the second power source line.

19. An integrated circuit comprising:
a plurality of processing circuits; and
a plurality of regulators that supply a power source voltage to each of the plurality of processing circuits, wherein
each of the plurality of regulators includes:
a transistor one of nodes of which is connected to a power source line and the other node of which is connected to an output node from which the power source voltage is output; and
an ESD protection circuit that temporarily brings the transistor into conduction when a surge voltage is applied to the power source line.
